(19) United States
(12) Patent Application Publication
(10) Pub. No.: US 2026/0136946 A1
(43) Pub. Date: May 14, 2026

(54) METHOD FOR PRODUCING A MEMS COMPONENT AND MEMS COMPONENT

(71) Applicant: Robert Bosch GmbH, Stuttgart (DE)

(72) Inventors: Andreas Finn, Dresden (DE); Christof Schwenk, Reutlingen (DE)

(21) Appl. No.: 19/384,714

(22) Filed: Nov. 10, 2025

(30) Foreign Application Priority Data
Nov. 13, 2024 (DE) 10 2024 210 898.7

(51) Int. Cl. H01L 23/544

(52) U.S. Cl. CPC H10W 46/00; H10W 46/301

(57) ABSTRACT

A method for producing a MEMS component. The MEMS component includes a layer stack of layers stacked in a Z-direction, wherein layers of the layer stack are successively deposited on a substrate and, lithographically structured in a defined alignment with respect to a reference plane to form layer structures. A lower layer of the layer stack exhibits at least one lower alignment mark in a defined alignment with respect to the reference plane. The lower alignment mark is detected for determining the alignment of the layer stack with respect to the reference plane by detecting electromagnetic radiation in the infrared spectral range, by detecting an infrared contrast. An upper layer is provided with a surface structuring in a defined alignment with respect to the reference plane. The surface structuring exhibits at least one upper alignment mark in a defined alignment with respect to the reference plane.

### CROSS REFERENCE

The present application claims the benefit under 35 U.S.C. § 119 of Germany Patent Application No. DE 102024 210 898.7 filed on November 13, 2024, which is expressly incorporated herein by reference in its entirety.

### FIELD

The present invention relates to a method for producing a MEMS component with a microelectromechanical system and the MEMS component produced according to the method, which can be designed, for example, as a MEMS sensor or MEMS actuator.

### BACKGROUND INFORMATION

In the production of MEMS components, a layer stack is typically formed from layers stacked on top of one another, wherein the layers are successively deposited on a substrate (also: wafer) and structured, in particular lithographically, in a defined alignment to one another. In order to ensure the prespecified alignment of the layer structures to be formed in the individual layers with respect to a reference plane, it is conventional to use one or more alignment marks (also: alignment structures) that are introduced as surface structuring in the substrate or in a lower layer of a layer stack already formed on the substrate. The alignment marks are structured so that the alignment of the substrate and/or of a layer stack already formed thereon with respect to the reference plane can be determined using an optical detection of the alignment marks. In particular, in exposure devices referred to as "steppers” or "scanners” in lithography, the alignment of the wafer or of the layer stack is clearly defined by the alignment marks, so that they make a precise exposure of a new layer possible with respect to the reference layer.

In this context, it is in particular conventional to structure alignment marks so that they generate a defined interference pattern that is uniquely determined by the orientation of the alignment mark with respect to the reference plane. Alternatively, conventional alignment marks can also be formed as significant surface structures, patterns or the like that are optically recognized with a camera. In this case, the alignment of the substrate and/or the layer stack already formed on it with respect to the reference plane is typically recognized using digital image processing methods, for example by image comparison.

However, the surface structures representing the alignment marks are typically covered by the successively deposited layers during the production of the semiconductor component, so that they increasingly lose their recognizability. In other cases, the applied layer is post-treated, in particular chemically and mechanically, wherein its topography is leveled, so that the alignment of the formed layer with respect to the reference plane with the aid of an optical detection of the alignment marks buried in the layer stack is difficult or may no longer be possible.

### SUMMARY

An object of the present invention is to provide a method for producing a MEMS component, wherein the precise alignment of the layer structures to be produced in the layers, in particular lithographically, with respect to a reference plane can be ensured.

The aforementioned object may be achieved by certain features of the present invention. Advantageous configurations of the present invention are disclosed herein.

A MEMS component within the scope of the present invention is a semiconductor component with a microelectromechanical system (MEMS), which typically comprises a movable structure integrated in the layer structure (also: layer stack) of the semiconductor component. In order to protect the movable structure, the MEMS component can optionally comprise a cap, which is likewise formed in the layer structure of the semiconductor component. The microelectromechanical system may represent a physical realization of, for example, a MEMS actuator, such as a loudspeaker, or a MEMS sensor, such as a pressure, ultrasonic and/or inertial sensor. Within the scope of these disclosures, such MEMS actuators or MEMS sensors are collectively referred to as MEMS components. Within the scope of this disclosure the direction of the layer sequence perpendicular to the lateral main extension plane of the layers is also referred to as the Z-direction.

In particular, a layer intended for the realization of the microelectromechanical system and/or an epitaxially grown layer of the layer stack may have a relatively large layer thickness. After the deposition of such a layer, the case may arise whereby the topography of an alignment mark covered by the layer does not produce an optically recognizable profile on the upper surface of the deposited layer. In this case, the alignment with respect to the reference plane can generally no longer be determined with sufficient certainty using conventional methods based on an optical detection of the alignment structuring.

Within the scope of this disclosure, the optical detection of the alignment structuring is to be understood as meaning that either the alignment mark itself or an assigned structuring formed on the upper surface of the layer stack, which is caused by the topography of an underlying alignment mark, is detected. Optical detection is carried out by detecting electromagnetic radiation in the visible spectral range. Within the scope of this disclosure, the visible spectral range is assigned a corresponding wavelength range between 400 nm and 700 nm. Within the scope of this disclosure, the infrared spectral range corresponds to a wavelength range between 750 nm and 1 mm.

If the alignment structuring is no longer sufficiently recognizable after layer deposition, the covered alignment mark is time-consumingly exposed again by removing material according to conventional production methods. However, such layer removal, for example by means of lithographic deep-etching, can only be carried out blindly and weakens the mechanical integrity of the layer stack formed on the substrate.

In contrast to this convention procedure, according to one aspect of the production method presented here according to the present invention, it is proposed to detect a lower alignment mark in order to determine the alignment of at least one upper layer structure of an upper layer of the layer stack by detecting electromagnetic radiation in the infrared spectral range, in particular by detecting an infrared contrast. The structures of covered alignment marks can still be sufficiently well recognized in the infrared, even with larger layer thicknesses, in particular as a contrast, in order to ensure the correct alignment of the layer structures to be formed with respect to the reference plane. In order to ensure this as well for the layers to be subsequently deposited and structured, it is provided according to an example embodiment of the present invention to introduce a surface structuring in the upper layer in a defined alignment with respect to the reference plane, wherein the surface structuring exhibits at least one upper alignment mark in a defined alignment with respect to the reference plane. This at least one upper alignment mark can then be used in the subsequent layer-forming method steps as an optically detectable alignment structuring for determining the alignment with respect to the reference plane. In a concrete embodiment of this idea, the lower alignment mark of the lower layer can be projected into the plane of the upper layer. The arrangement of the upper alignment marks in the lateral plane of the wafer or layer stack can be prespecified as desired; in particular, the upper alignment marks can be arranged inside or outside a useful chip region of the wafer, for example in an unstructured edge region of the wafer and/or in a region of the wafer that can be exposed by means of a photomask (reticle), in a test chip and/or in a scribe line.

Detecting the lower alignment mark in the infrared spectral range, in particular as infrared contrast, can be carried out reliably even in cases in which the lower alignment mark is covered by one or more intermediate layers. Here, since no alignment structures visible on the surface of the layer stack are detected, the alignment with respect to the reference plane can also take place after an abrasive, chemical-mechanical surface treatment (also: chemical-mechanical polishing / planarization, CMP), in which such alignment structures are leveled. In advantageous embodiments, the lower alignment mark is detected in the infrared after an abrasive, chemical-mechanical surface treatment, in particular of the upper layer and/or of an intermediate layer covering the lower alignment mark.

According to an example embodiment of the present invention, the surface structuring of the upper layer is preferably carried out lithographically, i.e., for this purpose a photoresist layer is applied to the upper layer, which is exposed by means of a mask aligned with respect to the reference plane and subsequently developed, wherein the unnecessary regions of the photoresist layer are removed. The actual structuring of the upper layer is carried out in a subsequent structuring step, in which the upper layer is removed in the exposed regions, in particular by wet chemical means or by plasma etching.

A further aspect of the present invention relates to the process-engineering integration of the provided procedure of the present invention into a process sequence for producing MEMS components. The at least one upper alignment mark is formed in accordance with the detected lower alignment mark in a structuring step which is preferably additionally used to introduce depressions for a further layer structure of a further layer. The further layer is deposited on the upper layer in subsequent method steps and structured to form the further layer structure so that it is formed in the depressions of the surface structuring of the upper layer in a defined alignment with respect to the reference plane.

Due to the further layer structure being formed in the depressions of the surface structuring of the upper layer, its effective topography is reduced. This has a particularly advantageous effect on subsequent lithographic structuring, in particular deep etching, of the upper layer, since in this way resist distortions can be avoided.

In some example embodiments of the present invention, the depressions in the surface structuring of the upper layer can be offset in the Z-direction relative to the surface of the upper layer by 0.3 nm to 2500 nm, preferably approximately 500 nm, particularly preferably 625 nm.

Preferably, the at least one upper alignment mark is detected in the visible spectral range in order to determine the alignment of the further layer structure with respect to the reference plane.

The further layer structure preferably forms at least one bonding region, in particular a bonding frame, for connecting the layer stack formed on the substrate to a further layer stack of the MEMS component. In an advantageous continuation, a local variation of the height of the further layer structure in the at least one bonding region can be provided in order to induce correspondingly high local forces during eutectic bonding. For this purpose, the surface structuring of the upper layer can comprise at least two regions offset with respect to the Z-direction and/or to a lateral direction, which bring about such a local variation of the height of the further layer structure in the at least one bonding region.

A further aspect of the present invention relates to a MEMS component produced according to the methods presented here.

Further details and advantages of the present invention are explained in more detail below with reference to the exemplary embodiments shown in the figures.

### BRIEF DESCRIPTION OF THE DRAWINGS

FIG. 1 shows a conventional method for producing a MEMS component.

FIG. 2 shows a method for producing a MEMS component according to a possible example embodiment according to the present invention.

FIGS. 3 to 6 show in detail method steps of the production method according to a possible example embodiment of the present invention.

FIG. 7 shows an exemplary embodiment of the present invention having a bonding region formed in a surface depression in an upper layer.

FIG. 8 shows a further exemplary embodiment of the present invention having a bonding region formed in a surface depression in an upper layer.

Identical or corresponding elements are provided with the same reference signs in all figures.

### DETAILED DESCRIPTION OF EXAMPLE EMBODIMENTS

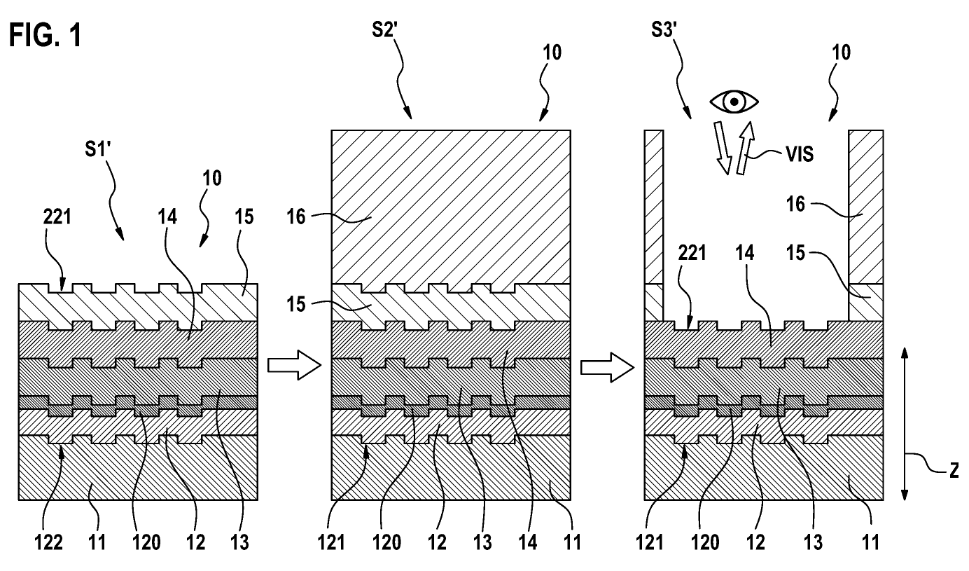

FIG. 1 illustrates a conventional production method for producing a MEMS component 1 using method steps S1', S2', S3'. Shown in each case is a layer stack 10, formed in the method steps S1', S2', S3', of layers 12, 120, 13, 14, 15, 16 deposited on a substrate 11. The substrate 11 can in particular be provided as a wafer, which forms a continuous substrate for producing a plurality of MEMS components 1.

In order to produce the MEMS component 1, the layers 12, 120, 13, 14, 15 are successively deposited on the substrate 11 and structured in a defined alignment with respect to a reference plane. In order to structure the layers 12, 120, 13, 14, 15 deposited on the substrate 11, the alignment of the layer stack 10 with respect to the reference plane is determined with the aid of a lower alignment mark 121. For this purpose, the lower alignment mark 121 has a topography or a height profile that forms an optically detectable alignment structuring 221 on the upper surface of the formed layer stack 10.

With the aid of the layer structure 10 shown by way of example in step S1' in FIG. 1, it is also evident that the optical recognizability of the alignment structuring 221 formed on the upper surface of the formed layer stack 10 is less than that of the lower alignment mark 121 of the lower layer since a plurality of intermediate layers 120, 13, 14, 15 overlay the lower alignment mark 121 in the layer stack direction, i.e. in the Z-direction Z. With reference to FIG. 1, it is evident, in particular with reference to the height profile shown, that the significance and thus the recognizability of the topography caused by the lower alignment mark 121 decreases in the intermediate layers 120, 13, 14, 15.

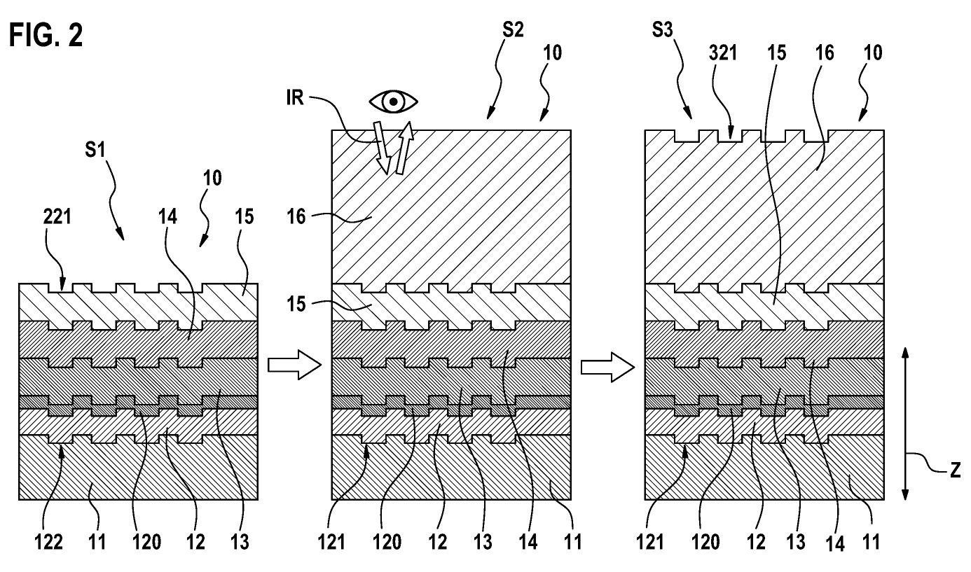

After the deposition of an upper layer 16 with a comparatively large layer thickness in step S2', as shown in FIG. 2, the recognizability of the alignment structures 221 on the visible side can be so limited that the alignment of the layer stack 10 with respect to the reference plane can no longer be determined with sufficient reliability. In particular in cases in which an abrasive surface treatment of the upper layer 16 is carried out for process-related reasons, the topography of the upper layer 16 can be leveled to such an extent that alignment structures 221 are no longer recognizable on the visible side and thus optical detection of the alignment mark 121 in the visible spectral range VIS is also not possible.

For this reason, according to the conventional procedure, in step S3' the lower alignment mark 121 is exposed in a blindly created trench above the expected position of the lower alignment mark 121, so that the alignment with respect to the reference plane can be determined in the subsequent method steps with the aid of the initial topography of the lower alignment mark 121. In the process, comparatively deep recesses or holes are formed in the layer stack 10, which impair the mechanical integrity of the layer stack 10 and may make additional protective measures necessary. In addition, the openings to be provided in the region of the alignment mark 121 typically exhibit in the Z-direction a comparatively large topography of 10 to 50 μm, which can lead, in particular during lithographic coating processes, to resist distortion and to etching in regions located radially outside and adjacent to the alignment mark 121. This can in particular cause malfunctions of the MEMS components 1 produced, in particular MEMS sensors.

FIG. 2 illustrates a method for producing the MEMS component 1 according to a possible embodiment of the present invention using method steps S1, S2, S3. Shown is the layer stack 10 formed in the method steps S1, S2, S3 from layers 12, 120, 13, 14, 15, 16 deposited on a substrate 11. The method steps S1 and S2 substantially correspond to the above-described embodiment with reference to the steps S1' and S2', so reference is made to the relevant description.

In contrast to the embodiment shown in FIG. 1, the hidden lower alignment mark 121 in the exemplary embodiment shown in FIG. 2 is detected in the infrared spectral range IR. Preferably, the hidden lower alignment mark 121 is detected as an infrared contrast, so that the alignment of the layer stack 10 formed on the substrate 11 with respect to the reference plane can be reliably detected even without layer removal. The corresponding method step of blindly exposing the lower alignment mark 121 can therefore be omitted.

In a step S3, the upper layer 16 is provided with a surface structuring 20, in particular lithographically. The surface structuring 20 exhibits at least one upper alignment mark 321, by means of which the alignment of the layer stack 10 with respect to the reference plane can be determined, in particular optically, in subsequent method steps. In a concrete embodiment of this idea, for example, the lower alignment mark 121 in the lower layer 12 can be projected into the upper layer 16.

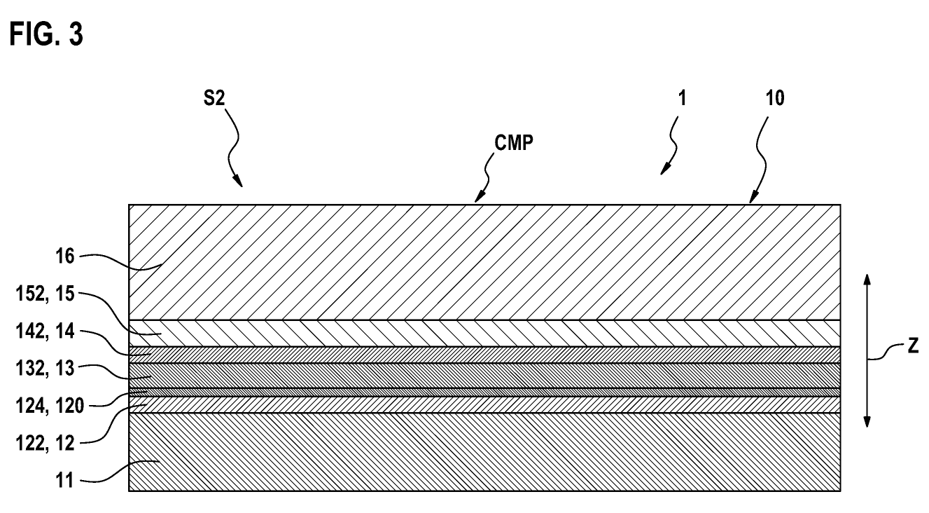

FIGS. 3 to 6 show in detail a method for producing MEMS components 1 according to an exemplary embodiment, wherein the progress of the production method is illustrated with the aid of sectional views of the layer stack 10 formed on the substrate 11 in the method steps S2, S3, S4, S41. Shown is a region of the layer stack 10 that, after the wafer has been divided into individual MEMS components 1, forms functional layers of the MEMS component 1.

The situation shown in FIG. 3 substantially corresponds to step S2 in FIG. 2. The layer stack 10 of layers 12, 120, 13, 14, 15, 16 was provided on the substrate 11, wherein the layers 12, 13, 14, 15 have already been structured, in particular lithographically, into layer structures 122, 124, 132, 142, 152. After its deposition, the upper layer 16 was subjected to an abrasive chemical-mechanical surface treatment (CMP). The alignment with respect to the reference plane is determined, as already explained with reference to FIG. 2, by detecting the lower alignment mark 121 in the infrared spectral range.

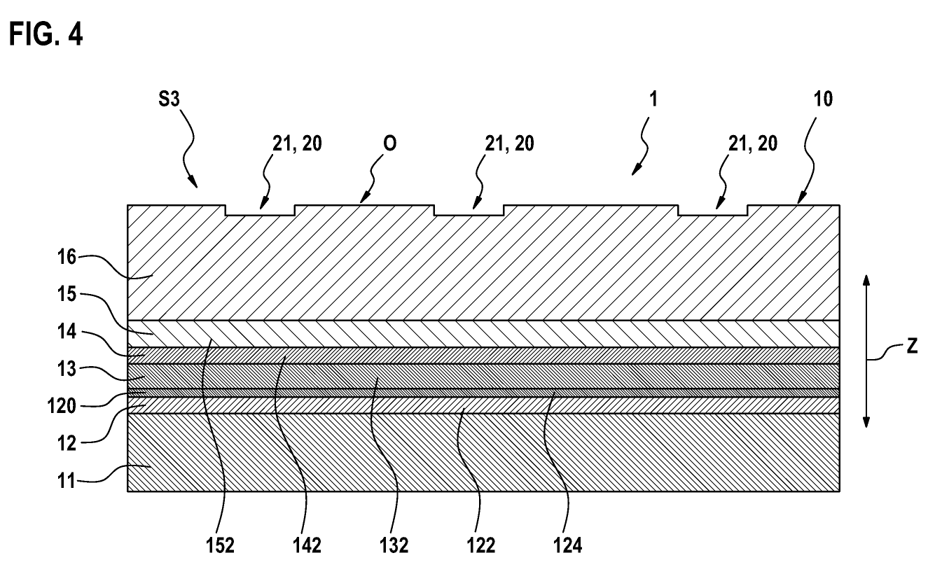

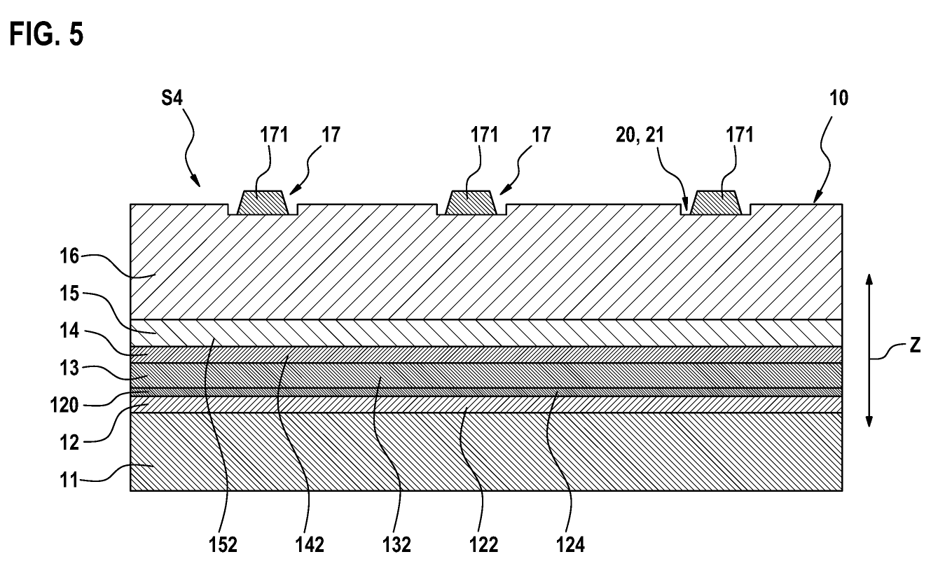

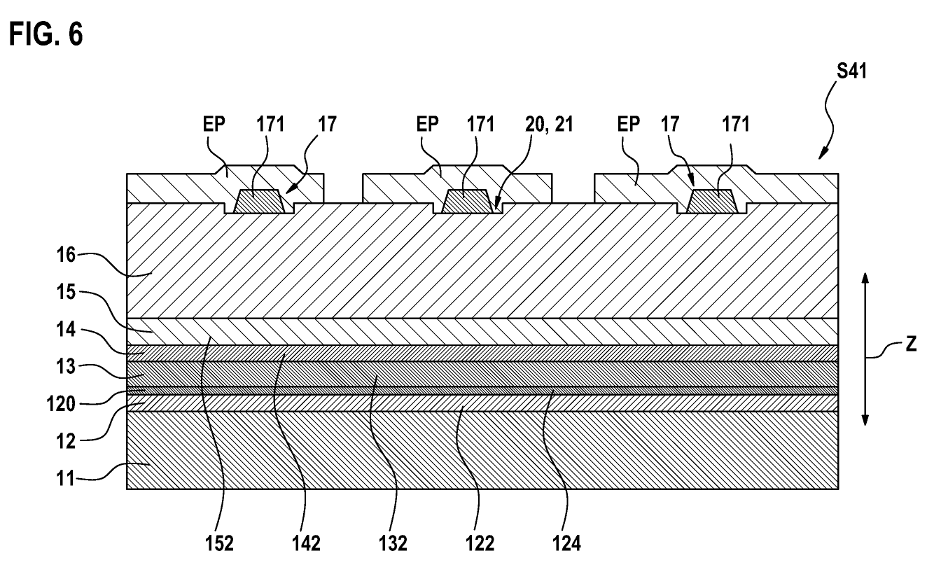

The situation shown in FIG. 4 substantially corresponds to step S3 in FIG. 2. In FIG. 4, it is shown in particular that the surface structuring 20 introduced in step S3 forms depressions 21 in which subsequently (see in particular FIGS. 5 and 6) further layer structures 171 of a further layer 17 are formed.

In the exemplary embodiment shown, the upper layer 16 consists of epitaxially grown polycrystalline silicon. The further layer 17 consists of a metal, in particular aluminum and/or copper. Since metallic layers are opaque to infrared radiation, the layer stack 10 is aligned with respect to the reference plane in the subsequent method steps with the aid of an optical detection of the upper alignment marks 321, i.e. by detecting electromagnetic radiation in the visible spectral range (see in particular FIG. 2).

The further layer structure 171 formed in the depressions 21 in the surface structuring 20 is shown in FIG. 5. The further layer structure 171 is produced by lithographic structuring. Starting from the situation shown in FIG. 3, in a step S4 the further layer 17 is deposited on the upper layer 16 of the layer stack 10 by means of a common deposition method, such as sputtering or vapor deposition. The further layer structure 171 is structured by a photoresist layer being applied to the newly formed further layer 17. The photoresist layer is exposed in regions with the aid of a mask, wherein the mask is aligned with respect to the reference plane after the deposition of the further layer 17 in accordance with an optical detection of the upper alignment marks 321 (see in particular FIG. 2) that can be detected on the visible side of the layer stack 10. After the photoresist has been developed, the underlying further layer 17 is etched, whereby the further layer 17 is structured into the further layer structure 171. FIG. 5 shows the situation after etching the further layer 17.

The depressions 21 in the upper layer 16 are arranged offset in the Z-direction Z relative to a surface O of the upper layer 16 by 0.3 nm to 2500 nm, preferably approximately 500 nm, particularly preferably 625 nm. The layer thickness of the further layer 17 in the Z-direction is between 800 nm and 1800 nm, preferably approximately 130 nm.

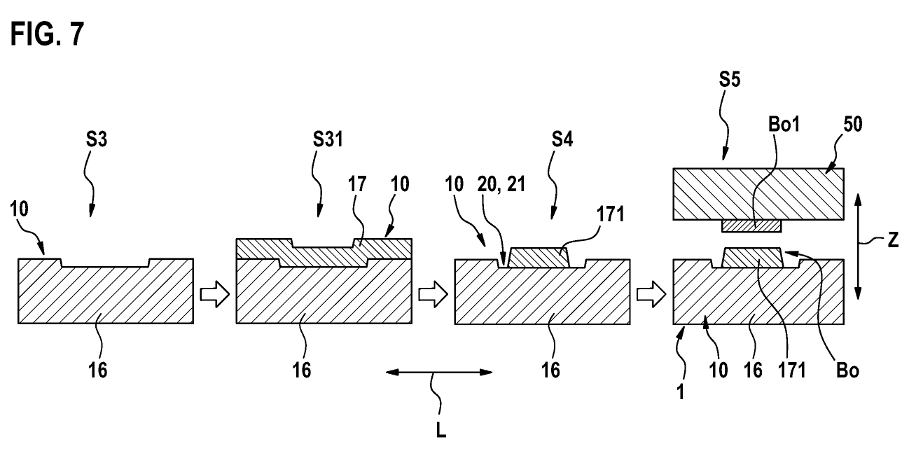

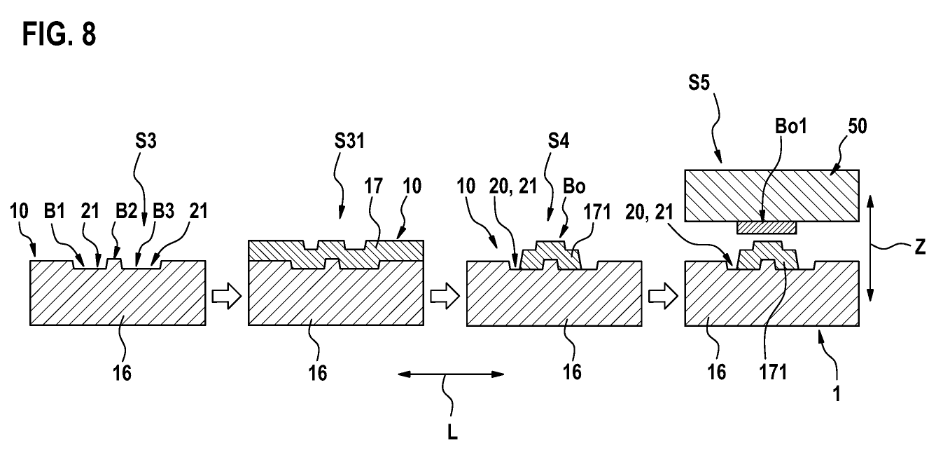

In the exemplary embodiment in FIG. 5, the further layer structure 171 provides at least one bonding region Bo, in particular bonding pad and bonding frame, for connecting the layer stack 10 formed on the substrate 11 to a further layer stack 50 (see in particular FIGS. 7 and 8). By the further layer structures 171 being formed in the depressions 20 in the upper layer 16, the effective topography of the structures formed on the upper surface of the layer stack 10 is reduced, so that resist distortions during subsequent lithography can be reduced or avoided.

In the exemplary embodiment in FIG. 6, a lithographic deep structuring of the upper layer (16) consisting of polycrystalline silicon is subsequently carried out, in particular using deep reactive-ion etching (DRIE). During this deep etching, components of the micromechanical system are formed. The reduction of the topography formed on the upper surface of the layer stack 10 advantageously results in a reduction of local fluctuations in the critical dimensions, in particular during the formation of a sensor structure of the MEMS component 1. Due to requirements of a subsequent wire bonding process the layer thickness of the further layer structure 171 can often only be reduced to a limited extent in order to reduce the effective topography.

FIG. 6 shows the layer stack 10 in a step S41, in which a photoresist layer EP has been applied for deep structuring of the upper layer 16. The photoresist layer EP also covers the further layer structure 171. The photoresist layer EP is exposed in regions by means of a mask, wherein the mask is aligned with respect to the reference plane in accordance with an optical detection of the upper alignment mark 321 (see in particular FIG. 2) that can be detected on the visible side of the layer stack 10. After development of the photoresist layer EP, the underlying upper layer 16 is removed in the exposed regions. The actual structuring of the upper layer 16 by means of deep ion etching is not explicitly shown in FIG. 6.

FIG. 7 schematically shows a method for producing the MEMS component 1, wherein the further layer structure 171 is formed as a bonding region Bo. In step S3, the surface structuring 20 of the upper layer 16 is formed so that it has at least one depression 21.

In step S31, the further layer 17, in particular as a metal layer containing aluminum and/or copper, is deposited over the surface, in particular by sputtering onto the upper surface 16. The depression 21 in the surface structuring 20 is completely covered.

In step S4, the lithographic structuring of the further layer 17 to form the further layer structure 171 is carried out. Here, the edge-side region of the further layer 17 is removed, so that the further layer structure 171 is located in the region of the depression 21.

In step S5, the formed layer stack 10 is bonded to a further layer stack 50. The further layer stack 50 is connected, on the one hand, via the bonding region Bo of the further layer structuring 171, and, on the other hand, via a further bonding region Bo1 of the further layer stack 50, in particular containing aluminum and/or copper.

FIG. 8 schematically shows a further method for producing the MEMS component 1, wherein the further layer structure 171 forms a bonding region Bo with a height profile. For this purpose, the surface structuring 20 of the upper layer 16 comprises regions B1, B2, B3 that are offset with respect to the Z-direction Z and a lateral direction L and that form a local variation of the height of the further layer structure 171 in the at least one bonding region Bo in the Z-direction Z. For this purpose, in step S3 the surface structuring 20 of the upper layer 16 is provided with the correspondingly offset regions B1, B2, B3. This can be carried out, for example, by providing two depressions 21 offset in the lateral direction L, as shown in FIG. 8.

In step S31, the further layer 17 is deposited as a metal layer containing aluminum and/or copper, in particular by sputtering onto the upper surface 16.

In step S4, the lithographic structuring of the further layer 17 to form the further layer structure 171 is carried out. In this case, the edge-side region of the further layer 17 is removed so that the further layer structure 171 in the region of the surface structuring 20 has a local variation of the height in the Z-direction.

In step S5, the formed layer stack 10 is bonded to the further layer stack 50 via the bonding regions Bo, Bo1. The local height variation of the bonding region Bo causes correspondingly high local forces during eutectic bonding, which can advantageously influence the properties of the final bond.

What is claimed is:

1. A method for producing a MEMS component, the MEMS component including a layer stack of layers stacked in a Z-direction, the method comprising the following steps:
successively depositing layers of the layer stack on a substrate and lithographically structureining the layers into layer structures in a defined alignment with respect to a reference plane, wherein a lower layer of the layers of the layer stack exhibits at least one lower alignment mark in a defined alignment with respect to the reference plane;
detecting the lower alignment mark for determining an alignment of the layer stack with respect to the reference plane by detecting electromagnetic radiation in an infrared spectral range including by detecting an infrared contrast; and
providing an upper layer of the layers of the layer stack with a surface structuring in a defined alignment with respect to the reference plane, wherein the surface structuring of the upper layer exhibits at least one upper alignment mark in a defined alignment with respect to the reference plane.

2. The method according to claim 1, wherein the surface structuring forms depressions for a further layer structure of a further layer, which is subsequently deposited on the upper layer, wherein the further layer structure is formed in a defined alignment with respect to the reference plane in the depressions in the surface structuring.

3. The method according to claim 2, wherein the at least one upper alignment mark is detected for determining the alignment of the further layer structure with respect to the reference plane, wherein electromagnetic radiation in a visible spectral range is detected.

4. The method according to claim 2, wherein the further layer structure forms at least one bonding region including a bonding frame, for connecting the layer stack formed on the substrate to a further layer stack of the MEMS component.

5. The method according to claim 4, wherein the surface structuring of the upper layer includes at least two regions that are offset with respect to: (i) the Z-direction and/or (ii) a lateral direction, and that form a local variation of a height of the further layer structure in the at least one bonding region in the Z-direction.

6. The method according to claim 2, wherein after the formation of the further layer structure, a deep structuring including lithographically, of the upper layer is carried out.

7. The method according to claim 2, wherein the further layer is formed by depositing including sputtering, a metal layer on a surface of the upper layer.

8. The method according to claim 2, the further layer is opaque to electromagnetic radiation in the infrared spectral range.

9. The method according to claim 2, wherein the depressions in the surface structuring of the upper layer (16) are arranged offset in the Z-direction relative to a surface of the upper layer by 0.3 nm to 2500 nm.

10. The method according to claim 2, wherein a layer thickness of the further layer extending in the Z-direction is between 800 nm and 1800 nm.

11. The method according to claim 2, wherein the upper layer is an epitaxially grown layer that includes monocrystalline or polycrystalline silicon.

12. The method according to claim 1, wherein the lower alignment mark in the lower layer is covered by at least one intermediate layer of the layers of the layer stack during its detectioned in the infrared spectral range.

13. The method according to claim 12, wherein a surface of the upper layer and/or the intermediate layer is abrasively treated using a chemical-mechanical surface treatment before formation of the surface structuring.

14. A MEMS component, wherein the mems component comprises a layer stack of layers stacked in a Z-direction, the MEMS component being produced by a method comprising the following steps:
successively depositing layers of the layer stack on a substrate and lithographically structureining the layers into layer structures in a defined alignment with respect to a reference plane, wherein a lower layer of the layers of the layer stack exhibits at least one lower alignment mark in a defined alignment with respect to the reference plane;
detecting the lower alignment mark for determining an alignment of the layer stack with respect to the reference plane by detecting electromagnetic radiation in an infrared spectral range including by detecting an infrared contrast; and
providing an upper layer of the layers of the layer stack with a surface structuring in a defined alignment with respect to the reference plane, wherein the surface structuring of the upper layer exhibits at least one upper alignment mark in a defined alignment with respect to the reference plane.
